(19) United States
(12) Patent Application Publication
(10) Pub. No.: US 2001/0031523 A1
(43) Pub. Date: Oct. 18, 2001

(54) Method of manufacturing semiconductor device having gate insulating films in different thickness

(75) Inventor: Naohiko Kimizuka, Tokyo (JP)

Correspondence Address: YOUNG & THOMPSON, 745 SOUTH 23RD STREET 2ND FLOOR, ARLINGTON, VA, 22202

(73) Assignee: NEC Corporation

(21) Appl. No.: 09/828,943

(22) Filed: Apr. 10, 2001

(30) Foreign Application Priority Data
Apr. 13, 2000 (JP) 2000-111503

(51) Int. Cl. H01L 21/8238; H01L 21/8242; H01L 21/336

(52) U.S. Cl. 438/200; 438/241; 438/258; 438/981

(57) ABSTRACT

A method of manufacturing a semiconductor device having a high Vth MOS FET and a low Vth MOS FET which have respective gate insulating films different in thickness from each other without covering the gate insulating film with a resist film. A silicon oxide film on a low Vth region is etched away, and in the nitriding process a nitride film is formed on the low Vth region. The silicon oxide film on a high Vth region is etched away without forming a resist film on the nitride film. A semiconductor substrate is thermally oxidized to form relatively a thick gate insulating film on the high Vth region and also to form a thin gate insulating film on the low Vth region. Gate electrodes are formed and then impurity diffusion layers forming a source and drain region are formed.

### BACKGROUND OF THE INVENTION

1. Field of the Invention

The present invention relates to a method of manufacturing MOS type semiconductor devices, and more particularly to a method of forming MOS transistors having gate insulating films which are different in thickness from each other.

2. Description of Related Art

Along with the increasing variety of apparatuses equipped with semiconductor integrated circuits, there is an increasing variety of circuit types, such as DRAM, SRAM and logic circuit, and a CPU portion and an I/O interface portion in a logic circuit, mounted together on the same semiconductor chip. In such a case, circuits requiring low current consumption, and circuits requiring high speed operation are mounted together on the same chip. On the other hand, high density and miniaturization are advancing, and consequently, in MOS type semiconductor devices, the thickness of the gate insulating films has been continuously decreasing in accordance with the scaling rule.

To reduce stand-by current due to sub-threshold leakage, circuits requiring low power consumption are made up of CMOS transistors having their threshold voltage set to a relatively high value. However, when the thickness of the gate insulating film is decreased in accordance with the scaling rule, the gate leakage current based on the direct tunnel phenomenon occurs. For example, when the thickness of the gate insulating film is less than or equal to 1.9 nm, a gate leakage current occurs which is larger in magnitude than the off-current (1.0 pA/μm) of a high threshold transistor. Such the gate leakage current determines the stand-by current. Consequently, the object of the low power consumption cannot be attained. For this reason, the thickness of the gate insulating film of a high threshold transistor in a low power consumption circuit conventionally cannot be reduced to a value less than or equal to about 2.5 nm.

On the other hand, transistors requiring high speed operation have their threshold voltage set to a low value. Since influence of the gate leakage current is relatively low, the thickness of the gate insulating film can be less than or equal to 2.0 nm. As a result, it is possible to improve the drain current. Therefore, For a low power consumption circuit and a high speed circuit to both be formed on one chip in an LSI or CMOS LSI, gate insulating films having different thicknesses must be formed.

But, in the case where the thickness of the gate insulating film is reduced, not only high gate leakage current, but also punch through of impurities, for example boron atoms, and degradation of hot carrier resistance become problems. It is known that in order to prevent the punch through of impurities, it is advantageous to employ a silicon nitride film. Furthermore, the hot carrier resistance of the silicon nitride film is superior to that of a silicon oxide film. For this reason, the silicon nitride film or the insulating film containing nitrogen is employed for a gate insulating film of reduced thickness.

FIGS. 3A to 3F are schematic cross-sectional views showing the steps of a conventional method of manufacturing a MOS type semiconductor device having two kinds of gate insulating films different in thickness from each other, as disclosed in Japanese Kokai No. Hei 4-154162. First of all, as shown in FIG. 3A, an element isolation insulating film 12 is formed in a semiconductor substrate 11 to partition the substrate into active regions and a first silicon oxide film 13 is formed on each of the active regions by thermal oxidation. Subsequently, as shown in FIG. 3B, heat treatment is carried out in N₂ or NH₃ atmosphere to nitride the whole surface. Thereafter, thermal oxidation is carried out for a short period in order to unify the film quality. The first silicon oxide film 13 is thereby transformed into a nitrided first silicon oxide film 14, which is employed as a first gate insulating film. Next, as shown in FIG. 3C, the left-hand side active region is covered with a photo resist film 15. The right-hand side active region is exposed, as the nitrided first silicon oxide film 14 which was located in that region has been etched away using for example hydrofluoric acid and the photo resist film 15 as a mask.

As shown in FIG. 3D, a second silicon oxide film 16 intended as a second gate insulating film is formed in the right-hand side active region by thermal oxidation. At this time, the nitrided first silicon oxide film 14 is hardly oxidized and hence the thickness thereof is hardly increased. Subsequently, as shown in FIG. 3E, gate electrodes 17 each made of polycrystalline silicon are formed on the first gate insulating film and the second gate insulating film, respectively. Next, as shown in FIG. 3F, after diffusion layers 18 are formed as a source and drain regions and then the whole surface is covered with an interlayer insulating film 19, a contact hole is formed therethrough. Thereafter, a wiring electrode 20 which is electrically connected to the diffusion layers 18 is formed, and the whole surface is covered with a cover insulating film 21 as a protective film.

As described above, the thickness of the first gate insulating film is hardly influenced by the process of forming the second gate insulating film. For this reason, the thickness of the second gate insulating film can be increased relative to the thickness of the first gate insulating film.

In the above-mentioned conventional method of manufacturing the gate insulating films having two different thicknesses, the first gate insulating film on one active region is covered with the photo resist film, and in this state, the insulating film on the other active region is etched away. If this method is employed, however, the first gate insulating film inevitably becomes contaminated with impurities from the photo resist film. In addition, when the photo resist film is removed and then cleaning is carried out, the first gate insulating film is damaged. Because the film quality of the gate insulating film, which is extremely thin (equal to or smaller than about 2 nm), is seriously influenced in the above-mentioned process, it becomes impossible to ensure the uniformity of the characteristics as well as the reliability of the products.

### SUMMARY OF THE INVENTION

An object of the present invention is to provide a method of manufacturing that solves the above-mentioned problems associated with the related art, and to provide a method of manufacturing in which a film that becomes a gate insulating film in the finished product does not need to be covered with a photo resist film.

Another object of the present invention is to ensure uniform film quality of the gate insulating film.

Furthermore, another object of the present invention is to ensure the reliability of the products.

A method of manufacturing a semiconductor device according to the present invention comprises the steps of: forming a first insulating film on a semiconductor substrate having first and second regions; selectively etching the first insulating film on the first region; forming a second insulating film on the first region after the first insulating film on the first region has been removed, the second insulating film having etching characteristics different from those of the first insulating film; removing the first insulating on the second region; forming third and fourth insulating films to cover the second insulating film and the second region, respectively; and forming a first gate electrode and a second gate electrode on the third insulating film and the fourth insulating film, respectively.

These and other objects of the present invention will be apparent to those of skill in the art from the appended claims when read in light of the following specification and accompanying figures.

### BRIEF DESCRIPTION OF THE DRAWINGS

FIGS. 1A to 1F are cross sectional views showing the steps of a manufacturing method of first and second embodiments of the present invention.

FIGS. 2A to 2F are cross sectional views showing the steps of a manufacturing method of a third embodiment of the present invention.

FIGS. 3A to 3F are cross sectional views showing the steps of a conventional manufacturing method.

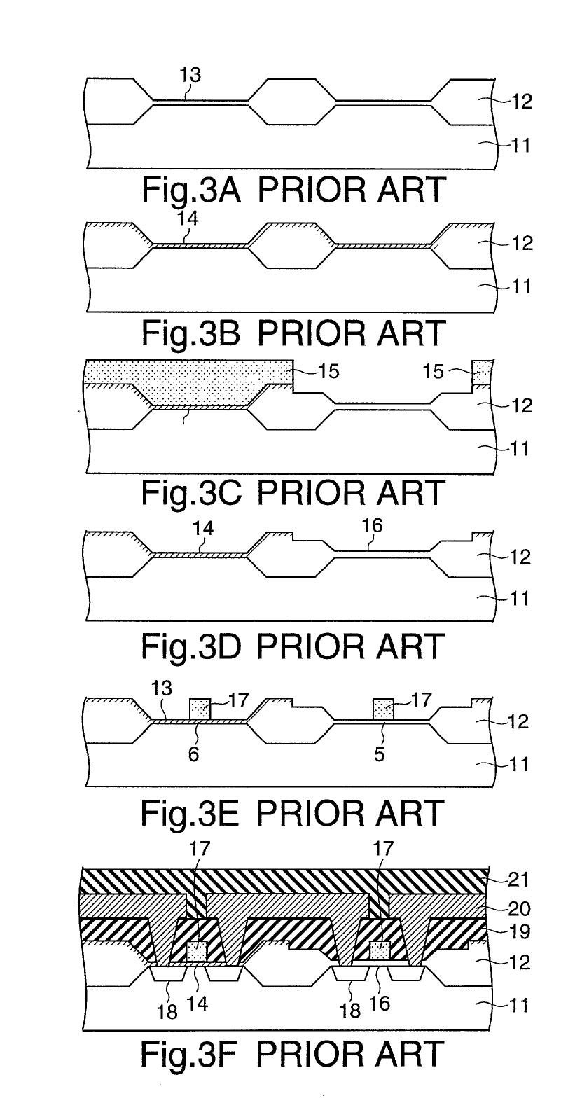

### DETAILED DESCRIPTION OF THE PREFERRED EMBODIMENTS

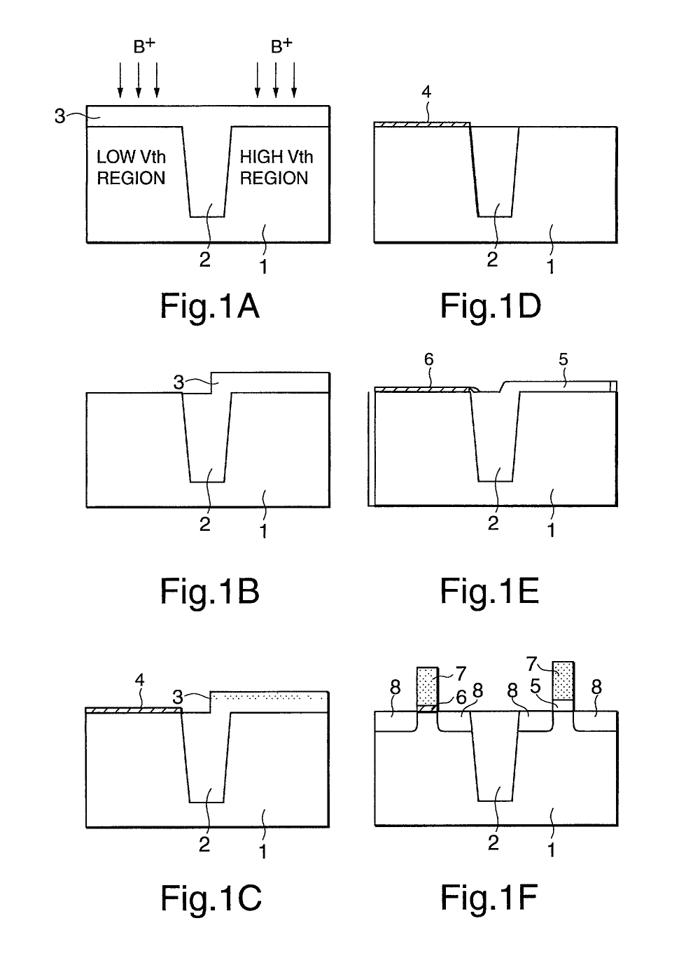

In FIGS. 1A to 1F, the semiconductor device includes MOS transistors having a low threshold voltage, whose absolute value is small, and MOS transistors having a high threshold voltage, whose absolute value is large. Both of the MOS transistors are formed on the same semiconductor chip.

First, as shown in FIG. 1A, an element isolation insulating film 2 of 350 nm thickness is formed on a semiconductor substrate 1 made of silicon by utilizing the trench method, and a first silicon oxide film 3 of 20 nm thickness is formed by utilizing the thermal oxidation method. Then, boron ions are implanted into the unmasked region of the substrate with the first silicon oxide film 3 as a cover oxide film in order to adjust the threshold voltages of the MOS FETs. Next, as shown in FIG. 1B, the formation region for a MOS transistor having a high threshold voltage (hereinafter referred to as a high Vth region) is covered with a photo resist film as a mask. The first silicon oxide film 3 on the formation region for a MOS transistor having a low threshold voltage (hereinafter referred to as a low Vth region) is etched away, together with the photo resist. After having removed the photo resist mask, as shown in FIG. 1C, heat treatment is carried out at 1,000 degrees C. for 30 seconds in NH₃ atmosphere to nitride the surface of the silicon substrate on the low Vth region. By this nitriding, a silicon nitride film 4 of 1 nm thickness is formed on the low Vth region. On the other hand, the surface of the first silicon oxide film 3 remaining on the high Vth region also gets implanted with nitrogen atoms.

Next, as shown in FIG. 1D, the above-mentioned silicon oxide film 3 which remains on the high Vth region and which has been implanted with nitrogen atoms is etched away by buffered hydrofluoric acid. During this etching process, the silicon nitride film 4 formed on the surface of the silicon substrate on the low Vth region is not etched away. Therefore, at this point, all insulating films contacted with photo resist have been removed. Subsequently, in order to deposit a gate insulating film, heat treatment is carried out at 1,000 degrees C. for 60 seconds in an oxygen atmosphere. As a result, as shown in FIG. 1E, a second silicon oxide film 5 is deposited on the surface of the silicon substrate on the high Vth region, while a silicon oxide film 6 containing therein nitrogen is deposited on the surface of a part of the substrate on the low Vth region. In this case, the deposition speed in the low Vth region is slower than that in the high Vth region because the low Vth region is covered with the silicon nitride film 4. As a result, a difference in thickness occurs, that is, the thickness of the second silicon oxide film 5 on the high Vth region is 2.8 nm, whereas the thickness of the silicon oxide film 6 containing therein nitrogen on the low Vth region is 1.8 nm. Subsequently, as shown in FIG. 1F, polycrystalline silicon is deposited thereon to form gate electrodes 7, and then ion implantation is carried out to form impurity diffusion layers 8 each becoming a source and drain region in accordance with the normal process of manufacturing CMOS LSIs.

In a second embodiment, when carrying out the nitriding process for the silicon substrate which has been described with reference to FIG. 1C in the above-mentioned first embodiment, ND₃ gas, a material in which the hydrogen in NH₃ molecules is replaced with deuterium, is employed instead of NH₃ gas. This improves resistance to the hot carrier of the devices. The reason for the improvement is that deuterium is received in the gate insulating film on the low Vth region, so that the Si-H bonding which is otherwise easily broken by the hot carriers is reformed into Si-D bonding which is much more difficult to break.

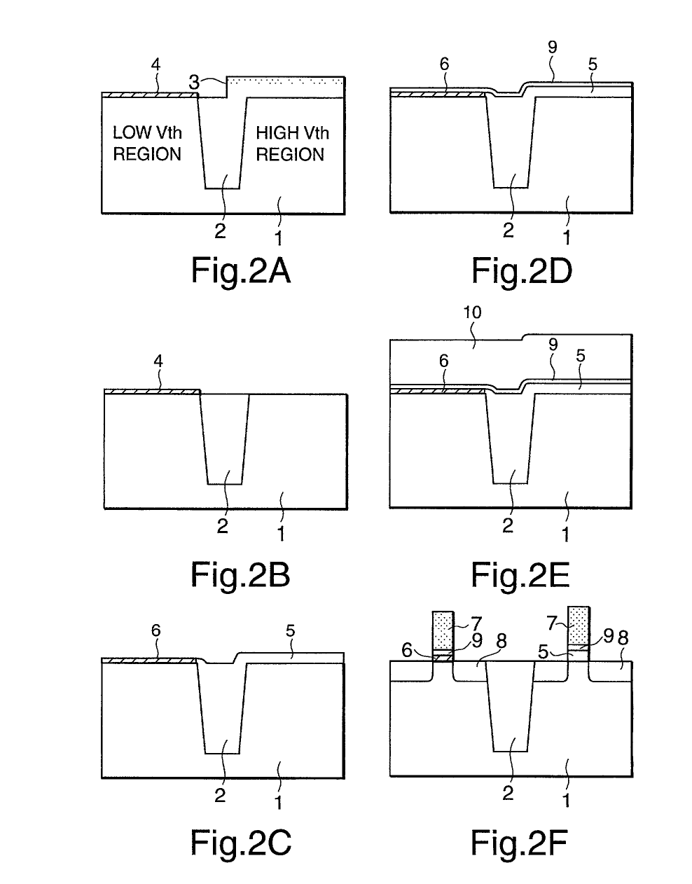

FIGS. 2A to 2F show schematic cross-sectional views showing the steps of a manufacturing method according to a third embodiment of the present invention. Since in the third embodiment the processes shown in FIG. 1A to 1B of the first embodiment are also carried out as described before, the illustration and description of the corresponding part(s) are omitted here for the sake of simplicity. After the process shown in FIG. 1B, as shown in FIG. 2A, the nitriding process is carried out at 1,000 degrees C. for 30 seconds in N₂ atmosphere to form a silicon nitride film 4 of 1 nm thickness on the silicon substrate of the low Vth region.

Next, as shown in FIG. 2B, the silicon oxide film 3 remaining on the surface of the silicon substrate in the high Vth region is etched away by buffered hydrofluoric acid. During this etching, the silicon nitride film 4 on the surface of the silicon substrate in the low Vth region is not etched away at all. Next, heat treatment is carried out at 800 degrees C. for 60 seconds in a wet oxygen atmosphere to form a second silicon oxide film 5 of 2.5 nm thickness on the surface of the silicon substrate in the high Vth region and also to form a silicon oxide film 6 of 1.5 nm thickness containing therein nitrogen on the surface of the silicon substrate in the low Vth region as shown in FIG. 2C.

Next, as shown in FIG. 2D, a tantalum oxide (Ta₂O₅) film of 1 nm thickness is deposited by the CVD method to form a high dielectric constant film 9 on the silicon oxide film 6 containing therein nitrogen and the second silicon oxide film 5. Subsequently, as shown in FIG. 2E, a polycrystalline silicon film of 15 nm thickness, a tungsten nitride film (WN) of 10 nm thickness, and a tungsten (W) film with 10 nm thickness are deposited in this order to form a multilayer conductive film 10.

Thereafter, as shown in FIG. 2F, a multilayer conductive film 10 is patterned to form gate electrodes 7 and then ion implantation is carried out to form impurity diffusion layers 8 each becoming a source and drain region.

According to the present invention, since gate insulating films having different thicknesses can be formed without ever contacting the final gate insulating film with photo resist, the gate insulating film is not contaminated from the photo resist and furthermore does not sustain damage resulting from the process of removing the photo resist film and the cleaning process. Therefore, according to the present invention, a thin gate insulating film can be formed with high reproducibility and high reliability, and hence a semiconductor device including a MOS FET which has a relatively thick insulating film and a high threshold voltage, and a MOS FET which has a relatively thin insulating film and a low threshold voltage can be provided with high reliability.

While preferred embodiments of the present invention have been described, it is to be understood that the invention is to be defined by the appended claims when read in light of the specification and when accorded their full range of equivalents. For example, the gate electrode may be formed of a metallic film having a high melting point, or a lamination film consisting of a polycide film or a polycrystalline silicon film and a high melting point metallic film. In addition, the high dielectric constant film, which is deposited on the oxide film and the nitride oxide film, may be made of other high dielectric constant material such as Tio₂ instead of the tantalum oxide. In addition, while in the above embodiments the substrate is nitrided directly, instead, thermal oxidation can be carried out first, and then nitriding performed for the resultant thermal oxide film. Furthermore, instead of removing the third silicon oxide film by wet etching, the third silicon oxide film removed by dry etching using HF gas or the like. Also, it is to be understood that the materials, numerical values and the like which have been described in the preferred embodiments are only by way of example, and hence the present invention is not limited thereto.

What is claimed is:

1. A method of manufacturing a semiconductor device comprising the steps of:
forming a first insulating film on a semiconductor substrate having first and second regions;
selectively etching said first insulating film on said first region;
forming a second insulating film on said first region after said first insulating film on said first region is removed by said selective etching, said second insulating film having etching characteristics different from those of said first insulating film;
removing said first insulating film on said second region;
forming a third insulating film and a fourth insulating film to cover said second insulating film and said second region, respectively; and
forming a first gate electrode and a second gate electrode on said third insulating film and said fourth insulating film, respectively.

2. The method as claimed in claim 1, wherein said second insulating film includes nitrogen.

3. The method as claimed in claim 1, wherein the step of forming said second insulating film is performed by nitriding said first region of said semiconductor substrate.

4. The method as claimed in claim 1, wherein the step of forming said second insulating film is performed by nitriding an oxide film formed by thermal oxidation.

5. The method as claimed in claim 1, wherein the step of forming said second insulating film is performed in a gas atmosphere containing nitrogen (N) and deuterium (D).

6. The method as claimed in claim 1, wherein the step of removing said first insulating film on said second region is performed by wet etching.

7. The method as claimed in claim 1, wherein the step of removing said first insulating film on said second region is performed by etching with a solution containing hydrogen fluoride (HF) as etchent.

8. The method as claimed in claim 1, wherein said third insulating film is thinner than said fourth insulating film.

9. The method as claimed in claim 1, wherein said third insulating film has a first thickness of not more than 2.0 nm and said fourth insulating film has a second thickness of not less than 2.5 nm.

10. The method as claimed in claim 1, further comprising the step of forming impurity diffusion layers in said first and second regions, respectively, in order to form a first transistor on said first region and a second transistor on said second region, said first transistor having a first threshold, said second transistor having a second threshold and said first threshold having a value lower than said second threshold.

11. The method as claimed in claim 1, further comprising the step of performing an ion implantation of impurities in said first and second regions through said first insulating film before the step of selectively etching said first insulating film, thereby to control thresholds of transistors to be formed on said first and second regions.

12. The method as claimed in claim 1, further comprising the step of forming a fifth insulating film having a high dielectric constant on said third and fourth insulating films before the step of forming said first and second gate electrodes.
